(19) United States
(12) Patent Application Publication
(10) Pub. No.: US 2026/0196172 A1
(43) Pub. Date: Jul. 9, 2026

(54) DISPLAY APPARATUS AND ELECTRONIC DEVICE INCLUDING THE SAME

(71) Applicant: Samsung Display Co., Ltd., Yongin-si (KR)

(72) Inventors: Kyeuk LEE, Yongin-si (KR); Sunkwang KIM, Yongin-si (KR); Sihyun AHN, Yongin-si (KR); Seungsoo BAEK, Yongin-si (KR); Seongyoung LEE, Yongin-si (KR)

(73) Assignee: Samsung Display Co., Ltd., Yongin-si (KR)

(21) Appl. No.: 19/351,856

(22) Filed: Oct. 7, 2025

(30) Foreign Application Priority Data
Jan. 6, 2025 (KR) 10-2025-0001833

(51) Int. Cl. G09G 3/3233; H10K 59/131

(52) U.S. Cl. CPC G09G 3/3233; H10K 59/131; G09G 2300/0426; G09G 2300/0465; G09G 2300/0819; G09G 2300/0842; G09G 2300/0861

(57) ABSTRACT

A display apparatus includes a sub-pixel, and the sub-pixel may include a sub-pixel circuit, a driving voltage line and a data line that extend in a first direction; an emission control line that extend in a second direction crossing the first direction; and a light-emitting diode. The sub-pixel circuit may include a driving transistor connected between the driving voltage line and the light-emitting diode, a data write transistor connected between the driving transistor and the data line, an emission control transistor connected between the driving voltage line and the driving transistor, and a first conductive pattern connected to the emission control line and including a gate electrode of the emission control transistor. The first conductive pattern may be between the driving voltage line and the driving transistor in a plan view.

### CROSS-REFERENCE TO RELATED APPLICATION

This application is based on and claims priority under 35 U.S.C. §119 to Korean Patent Application No. 10-2025-0001833, filed on January 6, 2025, in the Korean Intellectual Property Office, the disclosure of which is incorporated by reference herein in its entirety.

### BACKGROUND

### Field

One or more embodiments relate to a display apparatus and an electronic device including the same.

### Description of the Related Art

A display apparatus may include a plurality of pixels. Each pixel may include sub-pixels emitting light of different colors. Each sub-pixel may include a light-emitting element including an emission layer and a sub-pixel circuit configured to control brightness and other characteristics of the light-emitting element. The sub-pixel circuit may include transistors, capacitors, and lines.

Recently, the thickness and weight of the display apparatus have been reduced, and thus, the display apparatus may be employed by various electronic devices. As the display apparatus has been broadly used, a display panel in various forms and an electronic device including the display panel have been designed.

### SUMMARY

As the resolution of a display apparatus has increased, an area allocated for a pixel circuit has been reduced. With the reduction in the area of the pixel circuit, an arrangement of transistors, capacitors, and lines is required to be optimized. One or more embodiments include a display apparatus for providing a high-quality image by improving an arrangement of transistors, capacitors, and lines and an electronic device including the display apparatus. However, this objective is merely illustrative and does not limit the scope of embodiments of the disclosure.

Additional aspects will be set forth in part in the description which follows and, in part, will be apparent from the description, or may be learned by practice of the presented embodiments of the disclosure.

According to an aspect of the disclosure, a display apparatus includes a sub-pixel, and the sub-pixel may include: a sub-pixel circuit; a driving voltage line and a data line that extend in a first direction; an emission control line that extend in a second direction crossing the first direction; and a light-emitting diode. The sub-pixel circuit may include: a driving transistor connected between the driving voltage line and the light-emitting diode; a data write transistor connected between the driving transistor and the data line; an emission control transistor connected between the driving voltage line and the driving transistor; and a first conductive pattern connected to the emission control line and including a gate electrode of the emission control transistor. The first conductive pattern may be between the driving voltage line and the driving transistor in a plan view.

The first conductive pattern may extend in the first direction.

The display apparatus may further include an initialization-sensing line extending in the first direction and a control line extending in the second direction, wherein the sub-pixel circuit may further include an initialization-sensing transistor connected between the initialization-sensing line and the light-emitting diode and a second conductive pattern connected to the control line and including a gate electrode of the initialization-sensing transistor.

The emission control line may be closer to the control line than to a scan line of the sub-pixel in the plan view.

The emission control line may be arranged between the control line and the sub-pixel circuit in the plan view.

The control line may be arranged between the emission control line and the sub-pixel circuit in the plan view.

The display apparatus may further include a scan line extending in the second direction, wherein the sub-pixel circuit may further include a third conductive pattern connected to the scan line and including a gate electrode of the data write transistor.

The emission control line may be arranged to be closer to the scan line than to the control line.

According to one or more embodiments, the emission control line may be arranged between the scan line and the sub-pixel circuit.

According to one or more embodiments, the scan line may be arranged between the emission control line and the sub-pixel circuit.

An electronic device may include the display apparatus; a memory storing an application; and a processor configured to execute the application and transmit an image data signal and an input control signal to the display apparatus.

According to another aspect of the present disclosure, a display apparatus includes a first conductive layer including a driving voltage line extending in a first direction, a semiconductor layer arranged on the first conductive layer and including a first semiconductor pattern, a second conductive layer arranged on the semiconductor layer and including a first gate electrode overlapping a portion of the first semiconductor pattern and a first conductive pattern overlapping another portion of the first semiconductor pattern, and a third conductive layer arranged on the second conductive layer and including an emission control line extending in a second direction crossing the first direction, wherein the first conductive pattern extends in the first direction and is arranged between the driving voltage line and the first gate electrode in a plan view.

The first conductive layer may further include an initialization-sensing line extending in the first direction, the semiconductor layer may further include a second semiconductor pattern connected to the initialization-sensing line, the second conductive layer may further include a second conductive pattern extending in the first direction and overlapping the second semiconductor pattern, and the third conductive layer may further include a control line extending in the second direction and connected to the second conductive pattern.

The emission control line may be arranged to be closer to the control line than to the scan line in the plan view.

The emission control line may be arranged between the control line and the first gate electrode in the plan view.

The control line may be arranged between the emission control line and the first gate electrode in the plan view.

The first conductive layer may further include a data line extending in the first direction, the semiconductor layer may further include a third semiconductor pattern connected to the data line, the second conductive layer may further include a third conductive pattern extending in the first direction and overlapping the third semiconductor pattern, and the third conductive layer may further include a scan line extending in the second direction and connected to the third conductive pattern.

The emission control line may be arranged to be closer to the scan line than to the control line in the plan view.

The semiconductor layer may include an oxide-based semiconductor material.

An electronic device may include the display apparatus; a memory storing an application; and a processor configured to execute the application and transmit an image data signal and an input control signal to the display apparatus.

According to another aspect of the disclosure, an electronic device includes a pixel, and the pixel may include: a sensing line, a driving voltage line, and a data line that are sequentially arranged in a horizontal direction in a plan view of the pixel; a light emitting diode (LED); and a pixel circuit including: a first transistor between the driving voltage line and the LED; a storage capacitor connected between a gate electrode of the first transistor and the LED; a second transistor connected between the data line and the gate electrode of the first transistor; a third transistor connected between the sensing line and the LED; and a fourth transistor connected between the driving voltage line and the first transistor. A gate electrode of the fourth transistor may be connected to an emission control line that extends in the horizontal direction in the plan view. A gate wiring of the fourth transistor may extend in a vertical direction and may be between the driving voltage line and the storage capacitor in the plan view.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to one or more embodiments;

FIG. 2 is a schematic view of each of sub-pixels of a display apparatus, according to one or more embodiments;

FIG. 3 illustrates each of optical units of a color-conversion transmission layer of FIG. 2;

FIG. 4 is an equivalent circuit diagram of a sub-pixel included in a display apparatus according to one or more embodiments;

FIG. 5 is a schematic plan view of a portion of a display apparatus according to one or more embodiments;

FIGS. 6 to 8 are each a schematic plan view of each of layers of the portion of the display apparatus illustrated in FIG. 5;

FIG. 9 is a schematic cross-sectional view of the display apparatus illustrated in FIG. 5, taken along line I-I’;

FIGS. 10 to 12 are each a schematic plan view of a portion of a display apparatus according to one or more embodiments;

FIG. 13 is a block diagram of an electronic device according to one or more embodiments; and

FIGS. 14 to 16 are schematic views of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not limited to the embodiments disclosed hereinafter and may be realized in various forms.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

In the present disclosure, it will be understood that when an element, an area, or a layer is referred to as being connected to another element, area, or layer, it can be directly and/or indirectly connected to the other element, area, or layer. For example, it will be understood that when an element, an area, or a layer is referred to as being in contact with or being electrically connected to another element, area, or layer, it can be directly and/or indirectly in contact with or electrically connected to the other element, area, or layer.

In the present disclosure, the expression “A and/or B” may indicate A, B, or A and B. Also, the expression “at least one of A and B” may indicate A, B, or A and B.

In the present disclosure, an x direction, a y direction, and a z direction are not limited to directions in three axes on a rectangular coordinate system and may be interpreted in a broader sense. For example, the x direction, the y direction, and the z direction may be orthogonal to one another or may refer to different directions that are not orthogonal to one another.

In the present disclosure, the expression “in a plan view” denotes that an object part is downwardly viewed (for example, in a direction perpendicular to an upper surface of a substrate), and the expression “in a cross-sectional view” denotes that a vertical cross-section of an object part is laterally viewed.

In the present disclosure, that a first element “overlaps” a second element denotes that the first element is located above or below the second element so that at least portions of the first element and the second element overlap each other in a plan view.

In the present disclosure, the terms “on” and “off” used in relation to a device state refer to an activated state of the device and a non-activated state of the device, respectively. The terms “on” and “off” used in relation to a signal received by a device may refer to signals configured to activate the device and non-activate the device, respectively. A device may be activated by a high-level voltage or a low-level voltage. For example, a P-channel transistor (a P-type transistor) may be activated by a low-level voltage, and an N-channel transistor (an N-type transistor) may be activated by a high-level voltage. Thus, it shall be understood that “on” voltages with respect to the P-type transistor and the N-type transistor may be opposite voltages (low versus high) to each other.

In the present disclosure, when a certain embodiment may be implemented differently, a specific process order may be performed differently from the described order. For example, two consecutively described processes may be performed substantially at the same time or performed in an order opposite to the described order.

Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

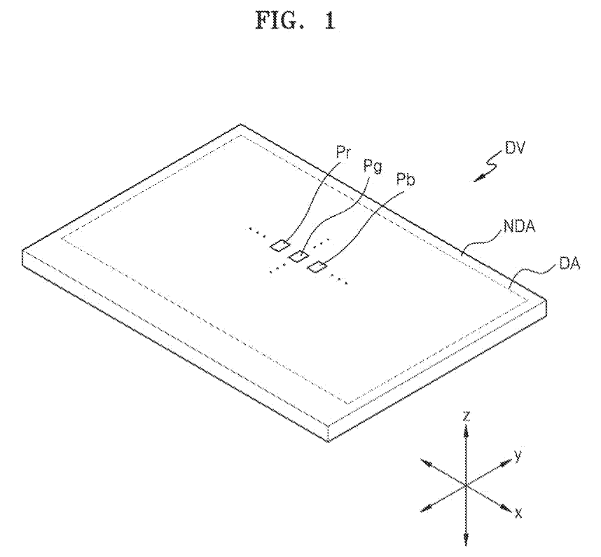

FIG. 1 is a schematic perspective view of a display apparatus DV according to one or more embodiments.

Referring to FIG. 1, the display apparatus DV may include a display area DA and a non-display area NDA outside the display area DA.

The display apparatus DV may provide an image through an array of a plurality of sub-pixels that are two-dimensionally arranged in the display area DA in a plan view. The plurality of sub-pixels may include a red sub-pixel Pr, a green sub-pixel Pg, and a blue sub-pixel Pb. The red sub-pixel Pr, the green sub-pixel Pg, and the blue sub-pixel Pb may correspond to areas for emitting red light, green light, and blue light, respectively, and the display apparatus DV may provide an image by using the light emitted from the sub-pixels.

The non-display area NDA may be an area which may not provide an image, and the non-display area NDA may entirely surround the display area DA. Drivers or voltage lines configured to provide electrical signals or power to sub-pixel circuits may be arranged in the non-display area NDA. The non-display area NDA may include a pad, which is an area to which an electronic device or a printed circuit board may be electrically connected.

The display area DA may have a polygonal shape. For example, the display area DA may have a rectangular shape having a horizontal length that is greater than a vertical length, as illustrated in FIG. 1. Alternatively, the display area DA may have a rectangular shape having a horizontal length that is less than a vertical length or may have a square shape. Alternatively, the display area DA may have various shapes, for example, an oval shape or a circular shape.

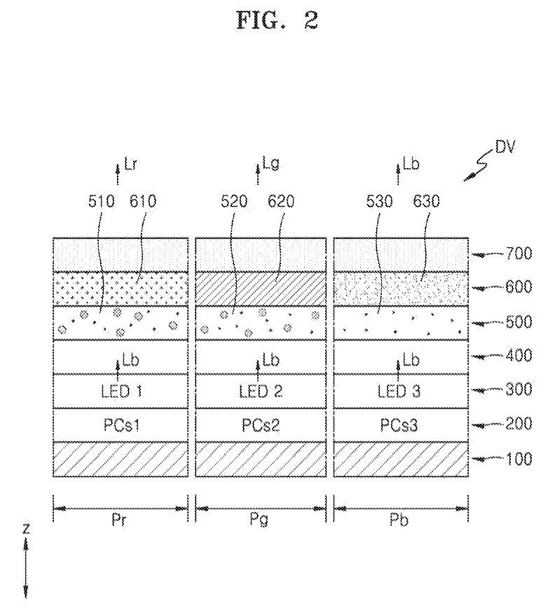

FIG. 2 is a schematic view of each sub-pixel of the display apparatus DV according to one or more embodiments.

Referring to FIG. 2, the display apparatus DV may include a circuit layer 200 on a substrate 100. The circuit layer 200 may include a first sub-pixel circuit PCs1, a second sub-pixel circuit PCs2, and a third sub-pixel circuit PCs3, and the first to third sub-pixel circuits PCs1 to PCs3 may be electrically connected to a first light-emitting diode LED 1, a second light-emitting diode LED 2, and a third light-emitting diode LED 3 of a light-emitting diode layer 300, respectively.

The first to third light-emitting diodes LED 1 to LED 3 may include organic light-emitting diodes including an organic material. According to another embodiment, the first to third light-emitting diodes LED 1 to LED 3 may include inorganic light-emitting diodes including an inorganic material. The inorganic light-emitting diode may include a PN junction diode including inorganic semiconductor-based materials. When a voltage is applied to the PN junction diode in a normal direction (i.e., a z-direction in FIG. 2), holes and electrons may be injected into the PN junction diode and energy generated by recombination of the holes and the electrons may be converted into light energy, and thus, light of a certain color may be emitted. The inorganic light-emitting diode described above may have a width that is several to hundreds of micrometers or several to hundreds of nanometers. According to some embodiments, the first to third light-emitting diodes LED 1 to LED 3 may be light-emitting diodes including quantum dots. As described above, emission layers of the first to third light-emitting diodes LED 1 to LED 3 may include organic materials, inorganic materials, quantum dots, organic materials and quantum dots, or inorganic materials and quantum dots.

The first to third light-emitting diodes LED 1 to LED 3 may emit light of the same color. For example, the first to third light-emitting diodes LED 1 to LED 3 may emit light (for example, blue light Lb) of a wavelength included in a first wavelength band. The first wavelength band may be between about 450 nm and about 495 nm. The light (for example, the blue light Lb) emitted from the first to third light-emitting diodes LED 1 to LED 3 may be transmitted through a color-conversion-transmission layer 500 by passing through an encapsulation layer 400 on the light-emitting diode layer 300.

The color-conversion-transmission layer 500 may include optical units configured to convert the color of the light emitted from the light-emitting diode layer 300 or transmit it without color conversion. For example, the color-conversion-transmission layer 500 may include color-conversion units configured to convert the light (for example, the blue light Lb) emitted from the light-emitting diode layer 300 into light of another color (e.g., red or green) and a transmission portion configured to transmit the light (for example, the blue light Lb) emitted from the light-emitting diode layer 300 without converting the color of the light. The color-conversion-transmission layer 500 may include a first color-conversion unit 510 corresponding to the red sub-pixel Pr, a second color-conversion unit 520 corresponding to the green sub-pixel Pg, and a transmission unit 530 corresponding to the blue sub-pixel Pb. The first color-conversion unit 510 may convert the light (for example, the blue light Lb) of the wavelength included in the first wavelength band into light (for example, red light Lr) of a wavelength included in a second wavelength band. The second wavelength band may be between about 630 nm and about 780 nm. The second color-conversion unit 520 may convert the light (for example, the blue light Lb) of the wavelength included in the first wavelength band into light (for example, green light Lg) of a wavelength included in a third wavelength band. The third wavelength band may be between about 495 nm and about 570 nm. The transmission unit 530 may transmit the light (for example, the blue light Lb) included in the first wavelength band without converting the light. However, the disclosure is not limited thereto, and the wavelength band of the light (for example, the blue light Lb) emitted from the light-emitting diode layer 300 and converted by the color-conversion-transmission layer 500 and a wavelength band including a wavelength of the light after the conversion may be modified to be different from the description above.

A color layer 600 may be arranged on the color-conversion-transmission layer 500. The color layer 600 may include a first color filter 610, a second color filter 620, and a third color filter 630, each configured to transmit light of different wavelength ranges corresponding to distinct colors. For example, the first color filter 610 may correspond to a red color filter transmitting only light of a wavelength of about 630 nm to about 780 nm. The second color filter 620 may correspond to a green color filter transmitting only light of a wavelength of about 495 nm to about 570 nm. The third color filter 630 may correspond to a blue color filter transmitting only light of a wavelength of about 450 nm to about 495 nm.

According to one or more embodiments, a black matrix may be optionally provided between the first to third color filters 610 to 630. According to another embodiment, the first color filter 610 may have an opening corresponding to the green sub-pixel Pg and the blue sub-pixel Pb, the second color filter 620 may have an opening corresponding to the red sub-pixel Pr and the blue sub-pixel Pb, and the third color filter 630 may have an opening corresponding to the red sub-pixel Pr and the green sub-pixel Pg. Portions of the first to third color filters 610 to 630 overlapping each another, excluding the openings corresponding to the red sub-pixel Pr, the green sub-pixel Pg, and the blue sub-pixel Pb, respectively, may perform a function like the black matrix by blocking unwanted light and enhancing image contrast.

The light whose color is converted by the color-conversion-transmission layer 500, as well as the light transmitted without color conversion may each have improved color purity by passing through the first through third color filters 610 through 630. Also, the color layer 600 may prevent or minimize a reflection of external light (for example, ambient light incident on the display apparatus DV from the outside of the display apparatus DV) and thereby may reduce glare and improve visibility for a user.

A transmissive substrate layer 700 may be provided on the color layer 600. The transmissive substrate layer 700 may include glass or a transmissive organic material. For example, the transmissive substrate layer 700 may include a transmissive organic material, such as acryl-based resins.

According to one or more embodiments, the transmissive substrate layer 700 may include a type of substrate, and after the color layer 600 and the color-conversion-transmission layer 500 are formed on the transmissive substrate layer 700, the substrate 100 and the transmissive substrate layer 700 may be integrated so that the color-conversion-transmission layer 500 and the color layer 600 face each other.

According to another embodiment, after the color-conversion-transmission layer 500 and the color layer 600 are sequentially formed on the encapsulation layer 400, the transmissive substrate layer 700 may be directly coated and cured on the color layer 600. According to some embodiments, another optical film, for example, an anti-reflection (AR) film, etc., may be arranged on the transmissive substrate layer 700.

The display apparatus DV having the structure described above may be included in an electronic device capable of displaying a motion image or a static image, such as a television, a billboard, a movie theater screen, a monitor, a tablet personal computer (PC), a notebook computer, etc.

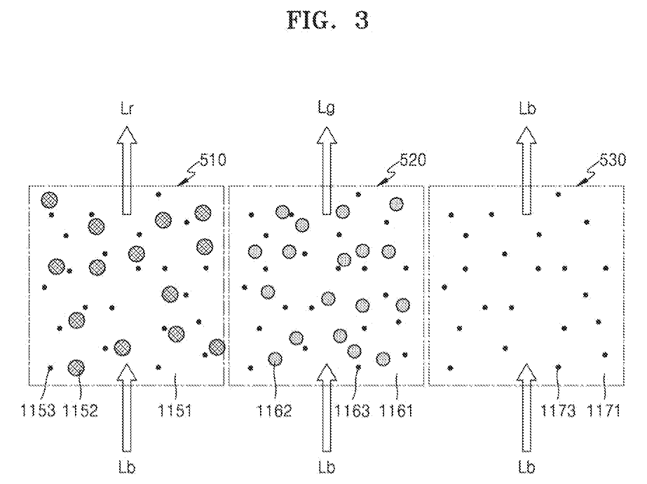

FIG. 3 illustrates each of the optical units of the color-conversion-transmission layer 500 of FIG. 2.

The first color-conversion unit 510 may convert the incident blue light Lb into the red light Lr. As illustrated in FIG. 3, the first color-conversion unit 510 may include a first photo-sensitive polymer 1151 and first quantum dots 1152 and first scattering particles 1153 distributed in the first photo-sensitive polymer 1151.

The first quantum dots 1152 may be excited by the blue light Lb and may emit, in an isotropic fashion, the red light Lr having a wavelength greater than a wavelength of the blue light Lb. The first photo-sensitive polymer 1151 may include a light-transmissive organic material.

Quantum dots may refer to nanoscale semiconductor crystals that emit light of various wavelengths according to the sizes of the crystals. The emission wavelength of the quantum dots is size-dependent, such that smaller dots emit light at shorter wavelengths, while larger dots emit light at longer wavelengths. A diameter of the quantum dots may be, for example, about 1 nm to about 10 nm.

The quantum dots may be synthesized by a wet chemical process, a metal organic chemical vapor deposition (MOCVD) process, a molecular beam epitaxy (MBE) process, or similar processes. The wet chemical process is a method by which an organic solvent is mixed with a precursor material, and then, quantum dot particle crystals are grown. According to the wet chemical process, when the crystals are grown, the organic solvent may naturally perform the function of a dispersant coordinated on a surface of the quantum dot crystals to control the growth of the crystals. Thus, the wet chemical process is more convenient than vapor deposition methods, such as the MOCVD or the MBE. Also, the wet chemical process costs reduced expenses and may control growth of quantum dot particles.

The quantum dots may include a groups III-VI semiconductor compound, a groups II-VI semiconductor compound, a groups III-V semiconductor compound, a groups I-III-VI semiconductor compound, a groups IV-VI semiconductor compound, a group IV element or compound, or any combination thereof.

Examples of the groups III-VI semiconductor compound may include a binary element compound, such as gallium sulfide (GaS), gallium selenide (GaSe), digallium triselenide (Ga₂Se₃), gallium telluride (GaTe), indium sulfide (InS), indium selenide (InSe), diindium triselenide (In₂Se₃), or indium telluride (InTe), a ternary element compound, such as indium gallium sulfide (InGaS₃) or indium gallium selenide (InGaSe₃), or any combination thereof.

Examples of the groups II-VI semiconductor compound may include a binary element compound, such as cadmium sulfide (CdS), cadmium selenide (CdSe), cadmium telluride (CdTe), zinc sulfide (ZnS), zinc selenide (ZnSe), zinc telluride (ZnTe), zinc oxide (ZnO), mercury(II) sulfide (HgS), mercury(II) selenide (HgSe), mercury(II) telluride (HgTe), magnesium selenide (MgSe), or magnesium sulfide (MgS), a ternary element compound, such as cadmium selenide sulfide (CdSeS, cadmium selenide telluride (CdSeTe), cadmium sulfide telluride (CdSTe), zinc selenide sulfide (ZnSeS), zinc selenide telluride (ZnSeTe), zinc sulfide telluride (ZnSTe), mercury(II) selenide sulfide (HgSeS), mercury(II) selenide telluride (HgSeTe), mercury(II) sulfide telluride (HgSTe), cadmium zinc sulfide (CdZnS), cadmium zinc selenide (CdZnSe), cadmium zinc telluride (CdZnTe), cadmium mercury(II) selenide (CdHgS), cadmium mercury(II) selenide (CdHgSe), cadmium mercury(II) telluride (CdHgTe), mercury(II) zinc sulfide (HgZnS), mercury(II) zinc selenide (HgZnSe), mercury(II) zinc telluride (HgZnTe), magnesium zinc selenide (MgZnSe), or magnesium zinc sulfide (MgZnS), a quaternary element compound, such as cadmium zinc selenide sulfide (CdZnSeS), cadmium zinc selenide telluride (CdZnSeTe), cadmium zinc sulfide telluride (CdZnSTe), cadmium mercury(II) selenide sulfide (CdHgSeS), cadmium mercury(II) selenide telluride (CdHgSeTe), cadmium mercury(II) sulfide telluride (CdHgSTe), mercury(II) zinc selenide sulfide (HgZnSeS), mercury(II) zinc selenide telluride (HgZnSeTe), or mercury(II) zinc sulfide telluride (HgZnSTe), or any combination thereof.

Examples of the groups III-V semiconductor compound may include a binary element compound, such as gallium nitride (GaN), gallium phosphide (GaP), gallium arsenide (GaAs), gallium antimonide (GaSb), aluminum nitride (AIN), aluminum phosphide (AIP), aluminum arsenide (AIAs), aluminum antimonide (AISb), indium nitride (InN), indium phosphide (InP), indium arsenide (InAs), or indium antimonide (InSb), a ternary element compound, such as gallium nitride phosphide (GaNP), gallium nitride arsenide (GaNAs), gallium nitride antimonide (GaNSb), gallium phosphide arsenide (GaPAs), gallium phosphide antimonide(GaPSb), aluminum nitride phosphide (AINP), aluminum nitride arsenide (AINAs), aluminum nitride antimonide (AINSb), aluminum phosphide arsenide (AIPAs), aluminum phosphide antimonide (AIPSb), indium gallium phosphide (InGaP), indium nitride phosphide (InNP), indium aluminum phosphide (InAIP), indium nitride arsenide (InNAs), indium nitride antimonide (InNSb), indium phosphide arsenide (InPAs), or indium phosphide antimonide (InPSb), a quaternary element compound, such as gallium aluminum nitride arsenide (GaAINAs), gallium aluminum nitride antimonide (GaAINSb), gallium aluminum nitride phosphide (GaAINP), gallium aluminum phosphide arsenide (GaAIPAs), gallium aluminum phosphide antimonide (GaAIPSb), gallium indium nitride phosphide (GaInNP), gallium indium nitride arsenide (GaInNAs), gallium indium nitride antimonide (GaInNSb), gallium indium phosphide arsenide (GaInPAs), gallium indium phosphide antimonide (GaInPSb), indium aluminum nitride phosphide (InAINP), indium aluminum nitride arsenide (InAINAs), indium aluminum nitride antimonide (InAINSb), indium aluminum phosphide arsenide (InAIPAs), or indium aluminum phosphide antimonide (InAIPSb), or any combination thereof. The groups III-V semiconductor compound may further include a group II element. Examples of the groups III-V semiconductor compound further including the group II element may include indium zinc phosphide (InZnP), indium gallium zinc phosphide (InGaZnP), or indium aluminum zinc phosphide (InAlZnP).

Examples of the groups I-III-VI semiconductor compound may include a ternary element compound, such as silver indium sulfide (AgInS), silver indium disulfide (AgInS₂), copper indium sulfide (CuInS), copper indium disulfide (CuInS₂), copper gallium oxide (CuGaO₂), silver gallium oxide (AgGaO₂), or silver aluminum oxide (AgAlO₂), or any combination thereof.

Examples of the groups IV-VI semiconductor compound may include a binary element compound, such as tin(II) sulfide (SnS), tin(II) selenide (SnSe), tin(II) telluride (SnTe), lead(II) sulfide (PbS), lead(II) selenide (PbSe), or lead(II) telluride (PbTe), a ternary element compound, such as tin selenide sulfide (SnSeS), tin selenide telluride (SnSeTe), tin sulfide telluride (SnSTe), lead selenide sulfide (PbSeS), lead selenide telluride (PbSeTe), lead sulfide telluride(PbSTe), tin lead sulfide (SnPbS), tin lead selenide (SnPbSe), or tin lead telluride (SnPbTe), a quaternary element compound, such as tin lead sulfide selenide (SnPbSSe), tin lead selenide telluride (SnPbSeTe), or tin lead sulfide telluride (SnPbSTe), or any combination thereof.

The group IV element or compound may include a single element compound, such as silicon (Si) or germanium (Ge), a binary element compound, such as silicon carbide (SiC) or silicon germanium (SiGe), or any combination thereof.

Each of elements included in the multi-element compounds, such as the binary element compound, the ternary element compound, and the quaternary element compound, may exist in particles by a uniform concentration or a non-uniform concentration.

Also, the quantum dot may have a single structure in which the concentration of each element included in the corresponding quantum dots is uniform or a core-shell dual structure. For example, a material included in the core may be different from a material included in the shell. The shell of the quantum dot may function as a protective layer for preventing chemical degeneration of the core and maintaining the semiconductor property and/or a charging layer for giving the quantum dot the electrophoretic property. The shell may include a single layer or multiple layers. An interface between the core and the shell may have a concentration gradient in which the concentration of an element of the shell decreases toward the center of the shell.

Examples of the shell of the quantum dot may include metal or nonmetal oxide, a semiconductor compound, or a combination thereof. Examples of the metal or nonmetal oxide may include a binary element compound, such as silicon dioxide (SiO₂), aluminum oxide (Al₂O₃), titanium dioxide (TiO₂), zinc oxide (ZnO), manganese(II) oxide (MnO), manganese(III) oxide (Mn₂O₃), manganese(II,III) oxide (Mn₃O₄), copper(II) oxide (CuO), iron(II) oxide (FeO), ron(III) oxide (Fe₂O₃), iron(II,III) oxide (Fe₃O₄), cobalt(II) oxide (CoO), cobalt(II,III) oxide (Co₃O₄), or nickel(II) oxide (NiO), a ternary element compound, such as magnesium aluminate (MgAl₂O₄), cobalt ferrite (CoFe₂O₄), nickel ferrite (NiFe₂O₄), or cobalt manganese oxide (CoMn₂O₄), or any combination thereof. Examples of the semiconductor compound may include the groups III-VI semiconductor compound, the groups II-VI semiconductor compound, the groups III-V semiconductor compound, the groups I-III-VI semiconductor compound, the groups IV-VI semiconductor compound, or any combination thereof, as described above. For example, the semiconductor compound may include cadmium sulfide (CdS), cadmium selenide (CdSe), cadmium telluride (CdTe), zinc sulfide (ZnS), zinc selenide (ZnSe), zinc telluride (ZnTe),zinc selenide sulfide (ZnSeS), zinc telluride sulfide (ZnTeS), gallium arsenide (GaAs), gallium phosphide (GaP), gallium antimonide (GaSb), mercury(II) sulfide (HgS), mercury(II) selenide (HgSe), mercury(II) telluride (HgTe), indium arsenide (InAs), indium phosphide (InP), indium gallium phosphide (InGaP), indium antimonide (InSb), aluminum arsenide (AlAs), aluminum phosphide (AlP), aluminum antimonide (AlSb), or any combination thereof.

The quantum dot may have the full width at half maximum (FWHM) of an emission wavelength spectrum that is about 45 nm or less, specifically, about 40 nm or less, and more specifically, about 30 nm or less, and in this range, a color purity or color reproduction may be improved. Also, the light emitted through this quantum dot may be emitted in all directions, and thus, a light viewing angle may be improved.

Also, shapes of the quantum dot may include a spherical shape, a pyramid shape, a shape of a multi-arm or cubic nanoparticle, nanotube, nanowire, nanofiber, or nano-plate-particle, etc.

An energy band gap may be adjusted by adjusting the size of the quantum dot, and thus, light of various wavelength bands may be obtained from the emission layer of the quantum dot. Thus, by using quantum dots having different sizes, a light-emitting diode emitting light of various wavelengths may be realized. In detail, the sizes of the quantum dots may be selected to emit red, green, and/or blue light. Also, the sizes of the quantum dots may be configured to combine light of various colors to emit white light.

The first scattering particles 1153 may excite an increased number of first quantum dots 1152 by scattering the blue light Lb not absorbed by the first quantum dots 1152, thereby improving the color-conversion efficiency. The first scattering particles 1153 may include, for example, metal oxide particles or organic particles. The metal oxides for the scattering particles may include TiO₂, zirconium(IV) oxide (ZrO₂), Al₂O₃, In₂O₃, ZnO, tin(IV) oxide (SnO₂₎, or the like, and the organic materials for the scattering particles may include acryl-based resins, urethane-based resins, or the like. The scattering particles may scatter the light in various directions regardless of an incident angle, without substantially converting the wavelength of the incident light. Accordingly, the scattering particles may improve the side visibility of a display apparatus.

The second color-conversion unit 520 may convert the incident blue light Lb into the green light Lg. As illustrated in FIG. 3, the second color-conversion unit 520 may include a second photo-sensitive polymer 1161 and second quantum dots 1162 and second scattering particles 1163 distributed in the second photo-sensitive polymer 1161.

The second quantum dots 1162 may be excited by the blue light Lb and may emit, in an isotropic fashion, the green light Lg having a wavelength greater than the wavelength of the blue light Lb. The second photo-sensitive polymer 1161 may include a light-transmissive organic material.

The second scattering particles 1163 may excite an increased number of second quantum dots 1162 by scattering the blue light Lb not absorbed by the second quantum dots 1162, thereby increasing the color-conversion efficiency. For the second quantum dots 1162 and the second scattering particles 1163, the descriptions above about the first quantum dots 1152 and the first scattering particles 1153 may be respectively referred to, and thus, the second quantum dots 1162 and the second scattering particles 1163 are not described.

According to some embodiments, the first quantum dots 1152 may include the same materials as the second quantum dots 1162. In this case, the sizes of the first quantum dots 1152 may be greater than the sizes of the second quantum dots 1162.

The transmission unit 530 may transmit the blue light Lb incident into the transmission unit 530 without color conversion. Thus, the transmission unit 530 may not include quantum dots. As illustrated in FIG. 3, the transmission unit 530 may include a third photo-sensitive polymer 1171 in which third scattering particles 1173 are distributed. The third photo-sensitive polymer 1171 may include, for example, a light-transmissive organic material, such as silicon resins, epoxy resins, etc., and may include the same material as the first and second photo-sensitive polymers 1151 and 1161. The third scattering particles 1173 may scatter and emit the blue light Lb and may include the same material as the first and second scattering particles 1153 and 1163.

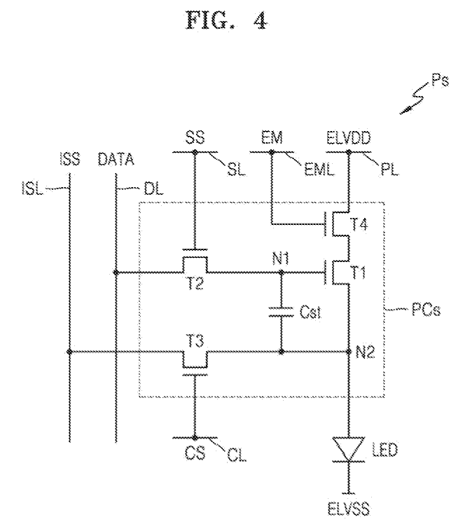

FIG. 4 is an equivalent circuit diagram of a sub-pixel included in the display apparatus DV according to one or more embodiments.

Referring to FIG. 4, one sub-pixel Ps included in the display apparatus DV (see FIG. 1) may include a light-emitting diode LED and a sub-pixel circuit PCs electrically connected to the light-emitting diode LED. FIG. 4 illustrates that the light-emitting diode LED corresponds to an organic light-emitting diode. A pixel electrode (for example, an anode) of the light-emitting diode LED may be electrically connected to the sub-pixel circuit PCs, and a common electrode (for example, a cathode) may be electrically connected to a common voltage line configured to transmit a common power voltage ELVSS.

The sub-pixel circuit PCs may include a first transistor T1, a second transistor T2, a third transistor T3, a fourth transistor T4, and a storage capacitor Cst. The sub-pixel circuit PCs may be electrically connected to signal lines and voltage lines. The signal lines may include a gate line, such as a scan line SL, a control line CL, and an emission control line EML, and a data line DL. The voltage lines may include a driving voltage line PL and an initialization-sensing line ISL.

The first transistor T1 may be a driving transistor. A first terminal of the first transistor T1 may be electrically connected, through the fourth transistor T4, to the driving voltage line PL configured to supply a driving power voltage ELVDD, and a second terminal of the first transistor T1 may be electrically connected to a second node N2. That is, the first transistor T1 may be electrically connected between the driving voltage line PL and the light-emitting diode LED. A gate electrode of the first transistor T1 may be connected to a first node N1. The first transistor T1 may be configured to control the amount of currents flowing through the light-emitting diode LED from the driving voltage PL, according to a voltage of the first node N1.

The second transistor T2 may be a data-write transistor. A first terminal of the second transistor T2 may be electrically connected to the data line DL, and a second terminal of the second transistor T2 may be electrically connected to the first node N1. That is, the second transistor T2 may be electrically connected between the data line DL and the first transistor T1. A gate electrode of the second transistor T2 may be electrically connected to the scan line SL. The second transistor T2 may be turned on when a scan signal SS is supplied to the scan line SL and may electrically connect the data line DL to the first node N1 to transmit a data signal DATA from the data line DL to the first node N1.

The third transistor T3 may be an initialization-sensing transistor. A first terminal of the third transistor T3 may be electrically connected to the initialization-sensing line ISL, and a second terminal of the third transistor T3 may be electrically connected to the second node N2. In other words, the third transistor T3 may be electrically connected between the initialization-sensing line ISL and the light-emitting diode LED. A gate electrode of the third transistor T3 may be electrically connected to the control line CL. When a control signal CS is supplied to the control line CL, the third transistor T3 may be turned on and may electrically connect the initialization-sensing line ISL to the second node N2 to transmit an initialization-sensing signal ISS from the initialization-sensing line ISL to the second node N2.

According to one or more embodiments, when the third transistor T3 is turned on, the third transistor T3 may use the initialization-sensing signal ISS from the initialization-sensing line ISL as an initialization voltage to initialize an electric potential of a pixel electrode of the light-emitting diode LED. Alternatively, when the third transistor T3 is turned on, the third transistor T3 may sense characteristics information of the light-emitting diode LED. As described above, the third transistor T3 may include both of the function as an initialization transistor and the function as a sensing transistor or may include either of the functions.

When the third transistor T3 has the function as the initialization transistor, the initialization-sensing line ISL may be considered as an initialization voltage line, and when the third transistor T3 has the function as the sensing transistor, the initialization-sensing line ISL may be considered as a sensing line. The initialization operation and the sensing operation of the third transistor T3 may be separately performed or simultaneously performed. In other words, the third transistor T3 may be an initialization transistor and/or a sensing transistor. Hereinafter, for convenience of explanation, a case where the third transistor T3 has both the function of the initialization transistor and the function of the sensing transistor is mainly described.

The fourth transistor T4 may be an emission control transistor. A first terminal of the fourth transistor T4 may be electrically connected to the driving voltage line PL, and a second terminal of the fourth transistor T4 may be electrically connected to the first terminal of the first transistor T1. That is, the fourth transistor T4 may be electrically connected between the driving voltage line PL and the first transistor T1, establishing an intermediate current path. A gate electrode of the fourth transistor T4 may be electrically connected to the emission control line EML. When an emission control signal EM is supplied to the emission control line EML, the fourth transistor T4 may be turned on and may form a current path for a driving current to flow in a direction from the driving voltage line PL to the light-emitting diode LED. When the fourth transistor T4 turns on, it effectively connects the first transistor T1 and the fourth transistor T4 in series, establishing a continuous current path. The emission control line EML may be used to regulate the on/off state of the fourth transistor T4. For example, when the emission control signal EM is high, the fourth transistor T4 is in the on state, allowing current flow. Conversely, when the emission control signal EM is low, the fourth transistor T4 remains in the off state, blocking the current path and thus controlling the emission of the LED. In this configuration, the fourth transistor T4 acts as an element in controlling the emission of light from the LED by regulating the current flow in the circuit, based on the emission control signal EM.

The storage capacitor Cst may be connected between the first node N1 and the second node N2. For example, a capacitor electrode of the storage capacitor Cst may be electrically connected to the gate electrode of the first transistor T1, and the other capacitor electrode of the storage capacitor Cst may be electrically connected to the pixel electrode of the light-emitting diode LED.

According to one or more embodiments, the first to fourth transistors T1 to T4 may include n-channel transistors. According to another embodiment, some of the first to fourth transistors T1 to T4 may include n-channel transistors and the others may include p-channel transistors. According to another embodiment, the first to fourth transistors T1 to T4 may include p-channel transistors.

According to one or more embodiments, the first to fourth transistors T1 to T4 may include oxide semiconductor thin-film transistors including semiconductor layers including an oxide semiconductor. According to another embodiment, some of the first to fourth transistors T1 to T4 may include oxide semiconductor thin-film transistors, and the others may include silicon semiconductor thin-film transistors including semiconductor layers including polysilicon. According to another embodiment, the first to fourth transistors T1 to T4 may include silicon semiconductor thin-film transistors.

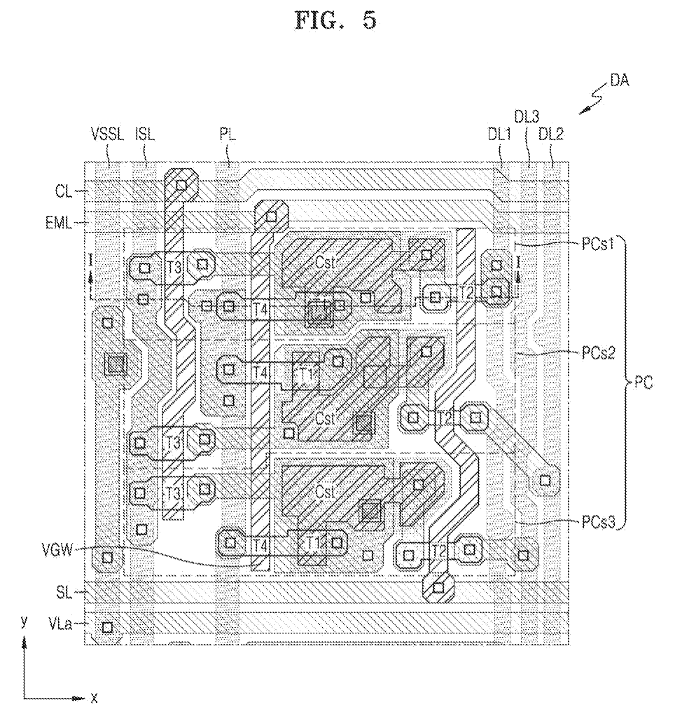

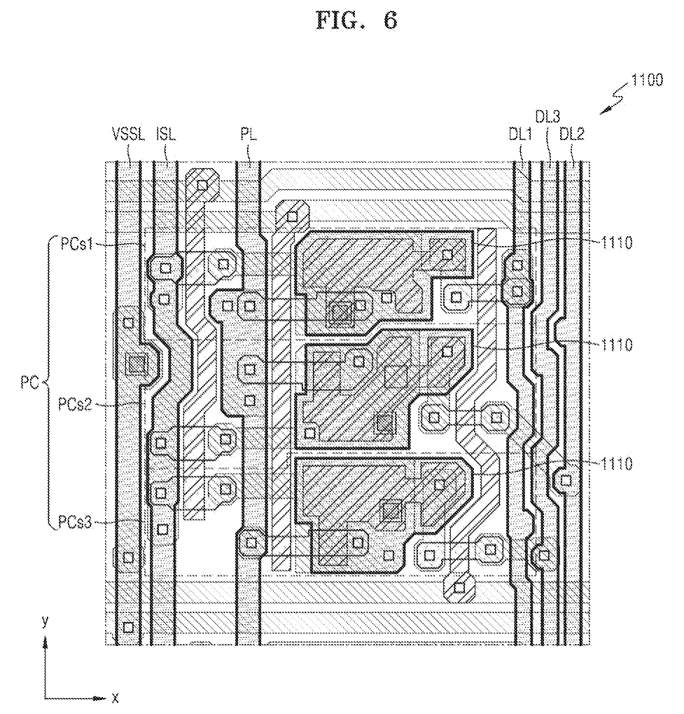

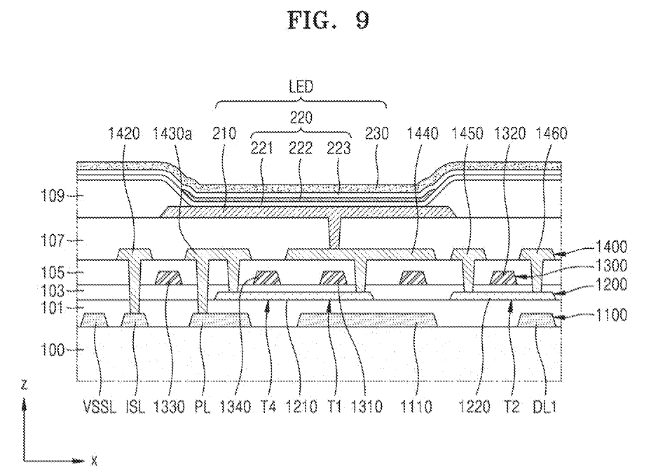

FIG. 5 is a schematic plan view of a portion of a display apparatus according to one or more embodiments, and FIGS. 6 to 8 are each a plan view of each of layers of the portion of the display apparatus illustrated in FIG. 5. FIG. 9 is a schematic cross-sectional view of the display apparatus illustrated in FIG. 5, taken along line I-I’.

Referring to FIG. 5, a pixel circuit PC may be arranged in the display area DA. One pixel circuit PC may include a plurality of sub-pixel circuits, for example, the first to third sub-pixel circuits PCs1, PCs2, and PCs3. For example, the pixel circuit PC may include the first sub-pixel circuit PCs1 electrically connected to a first light-emitting diode emitting light of a first color, the second sub-pixel circuit PCs2 electrically connected to a second light-emitting diode emitting light of a second color, and the third sub-pixel circuit PCs3 electrically connected to a third light-emitting diode emitting light of a third color. According to one or more embodiments, the first color may be green, the second color may be red, and the third color may be blue, but the disclosure is not limited thereto. The order of the first to third sub-pixel circuits PCs1 to PCs3 in a first direction (for example, a y axis direction) may be differently designed according to necessity.

The first to third sub-pixel circuits PCs1 to PCs3 may be sequentially arranged in the first direction (for example, the y axis direction) and may be electrically connected to signal lines and voltage lines. The signal lines may include first to third data lines DL1, DL2, and DL3, a control line CL, an emission control line EML, and a scan line SL. The voltage lines may include a common voltage line VSSL, an initialization-sensing line ISL, a driving voltage line PL, and an auxiliary voltage line VLa. The emission control line EML may be connected to a gate electrode of the fourth transistor T4 via a vertical gate wiring VGW that extends in the vertical direction (e.g., along the y-axis direction). For example, the vertical gate wiring VGW for the fourth transistor T4 may be positioned between the driving voltage line PL and the storage capacitor Cst in the horizontal direction (e.g., along the x-axis direction).

Each of the first to third sub-pixel circuits PCs1 to PCs3 may include the first to fourth transistors T1 to T4 and the storage capacitor Cst. The first to third sub-pixel circuits PCs1 to PCs3 may include elements configured to perform similar or substantially the same functions. Unless specifically described, each of the second and third sub-pixel circuits PCs2 and PCs3 may include the elements corresponding to the elements included in the first sub-pixel circuit PCs1. The portion illustrated in FIG. 6 may indicate a unit area repeatedly arranged in a first direction (for example, a y axis direction) and a second direction (for example, an x axis direction).

Referring to FIGS. 6 and 9 together, a first conductive layer 1100 may be arranged on the substrate 100. The first conductive layer 1100 may include a conductive material, such as molybdenum (Mo), aluminum (Al), copper (Cu), titanium (Ti), etc., and may include a single layer or layers including the materials described above.

The first conductive layer 1100 may include the common voltage line VSSL, the initialization-sensing line ISL, the driving voltage line PL, the first to third data lines DL1 to DL3, and first conductive patterns 1110.

The common voltage line VSSL may extend in the first direction (for example, the y axis direction) and may be configured to transmit the common power voltage ELVSS (see FIG. 4) to the common electrode of the light-emitting diode LED (see FIG. 3). The initialization sensing-line ISL may extend in the first direction (for example, the y axis direction) and may be configured to transmit the initialization-sensing signal ISS to the pixel circuit PC. The driving voltage line PL may extend in the first direction (for example, the y axis direction) and may be configured to transmit the driving power voltage ELVDD (see FIG. 4) to the pixel circuit PC.

Each of the first to third data lines DL1 to DL3 may extend in the first direction (for example, the y axis direction). The first data line DL1 may be configured to transmit a first data signal to the first sub-pixel circuit PCs1, the second data line DL2 may be configured to transmit a second data signal to the second sub-pixel circuit PCs2, and the third data line DL3 may be configured to transmit a third data signal to the third sub-pixel circuit PCs3.

According to one or more embodiments, the common voltage line VSSL, the initialization-sensing line ISL, the driving voltage line PL, and the first to third data lines DL1 to DL3 may be sequentially arranged in the second direction (for example, the x axis direction). Here, FIG. 5 illustrates that the first data line DL1, the third data line DL3, and the second data line DL2 are sequentially arranged in the second direction (for example, the x axis direction). However, the disclosure is not limited thereto. The arrangement order of the first to third data lines DL1 to DL3 may be differently designed according to necessity.

The pixel circuit PC may include the first to third sub-pixel circuits PCs1 to PCs3, and each of the first to third sub-pixel circuits PCs1 to PCs3 may include the first conductive pattern 1110. In other words, the first conductive pattern 1110 may be arranged between the driving voltage line PL and the first data line DL1 in a plan view. The first conductive pattern 1110 may have an isolated shape.

A first insulating layer 101 may be arranged on the first conductive layer 1100. The first insulating layer 101 may include an inorganic insulating material, such as silicon oxide, silicon nitride, and silicon oxynitride, and may include plural layers or a single layer including the materials described above.

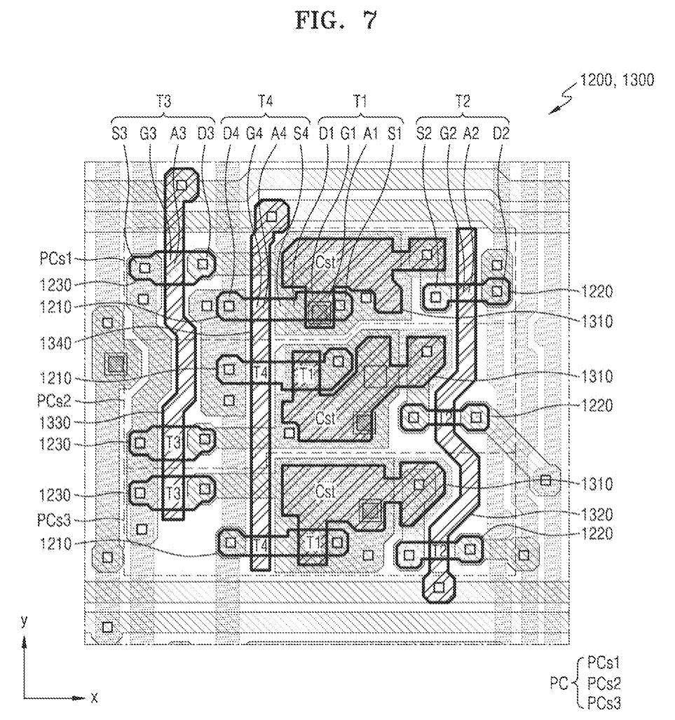

Referring to FIGS. 7 and 9 together, a semiconductor layer 1200 may be arranged on the first insulating layer 101. The semiconductor layer 1200 may include an oxide-based semiconductor material, for example, an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and Zn. According to one or more embodiments, the semiconductor layer 1200 may include In-Ga-Zn-O (IGZO) or In-Sn-Ga-Zn-O (ITGZO). According to another embodiment, the semiconductor layer 1200 may include a silicon-based semiconductor material, for example, polysilicon. The semiconductor layer 1200 may include first semiconductor patterns 1210, second semiconductor patterns 1220, and third semiconductor patterns 1230. The first semiconductor pattern 1210, the second semiconductor pattern 1220, and the third semiconductor pattern 1230 may be provided in each of the first to third sub-pixel circuits PCs1 to PCs3.

A second insulating layer 103 may be arranged on the semiconductor layer 1200. The second insulating layer 103 may include an inorganic insulating material, such as silicon oxide, silicon nitride, and silicon oxynitride and may include layers or a single layer including the materials described above.

A second conductive layer 1300 may be arranged on the second insulating layer 103. The second conductive layer 1300 may include a conductive material, such as Mo, Al, Cu, Ti, etc., and may include layers or a single layer including the materials described above. The second conductive layer 1300 may include second conductive patterns 1310, a third conductive pattern 1320, a fourth conductive pattern 1330, and a fifth conductive pattern 1340. The second conductive pattern 1310 may be provided in each of the first to third sub-pixel circuits PCs1 to PCs3, and each of the third conductive pattern 1320, the fourth conductive pattern 1330, and the fifth conductive pattern 1340 may extend in the first direction (for example, the y axis direction) and may be commonly provided in the first to third sub-pixel circuits PCs1 to PCs3.

The first semiconductor pattern 1210 may extend in the second direction (for example, the x axis direction) from the driving voltage line PL to overlap the first conductive pattern 1110 and the second conductive pattern 1310. The second conductive pattern 1310 may be arranged to overlap the first conductive pattern 1110 in a plan view.

The second conductive pattern 1310 may include a first gate electrode G1 of the first transistor T1 and an upper electrode of the storage capacitor Cst. In other words, the first gate electrode G1 of the first transistor T1 and the upper electrode of the storage capacitor Cst may be integrally provided. In this disclosure, the second conductive pattern 1310 may be referred to as the first gate electrode G1 of the first transistor T1. The first semiconductor pattern 1210 may include a first channel area A1 overlapping the first gate electrode G1, a first source area S1 and a first drain area D1 arranged at both sides of the first channel area A1. The first conductive pattern 1110 may include a lower electrode of the storage capacitor Cst and may form the storage capacitor Cst with the second conductive pattern 1310. The first conductive pattern 1110 may overlap the first channel area A1 of the first transistor T1 in a plan view and may prevent deterioration of the first transistor T1 caused by external light, etc.

An end of the second semiconductor pattern 1220 may be arranged to overlap a corresponding data line in a plan view. The third conductive pattern 1320 may be arranged between the first conductive patterns 1110 and the first to third data lines DL1 to DL3 in a plan view and may overlap the second semiconductor patterns 1220. The third conductive pattern 1320 may include a second gate electrode G2 of the second transistor T2 of each of the first to third sub-pixel circuits PCs1 to PCs3. The second semiconductor pattern 1220 may include a second channel area A2 overlapping the second gate electrode G2, a second source area S2 and a second drain area D2 arranged at both sides of the second channel area A2.

An end of the third semiconductor pattern 1230 may be arranged to overlap the initialization-sensing line ISL in a plan view. The fourth conductive pattern 1330 may extend in the first direction (for example, the y axis direction) and may be arranged between the initialization-sensing line ISL and the driving voltage line PL in a plan view. The fourth conductive pattern 1330 may overlap the third semiconductor patterns 1230. The fourth conductive pattern 1330 may include a third gate electrode G3 of the third transistor T3 of each of the first to third sub-pixel circuits PCs1 to PCs3. The third semiconductor pattern 1230 may include a third channel area A3 overlapping the third gate electrode G3, and a third source area S3 and a third drain area D3 arranged at both sides of the third channel area A3.

The fifth conductive pattern 1340 may be arranged between the driving voltage line PL and the second conductive patterns 1310 in a plan view and may overlap the first semiconductor patterns 1210. In other words, the fifth conductive pattern 1340 may be arranged between the driving voltage line PL and the first transistor T1 in a plan view. The fifth conductive pattern 1340 may include a fourth gate electrode G4 of the fourth transistor T4 of each of the first to third sub-pixel circuits PCs1 to PCs3. The first semiconductor pattern 1210 may include a fourth channel area A4 overlapping the fourth gate electrode G4, a fourth source area S4 and a fourth drain area D4 arranged at both sides of the fourth channel area A4.

A third insulating layer 105 may be arranged on the second conductive layer 1300. The third insulating layer 105 may include an inorganic insulating material, such as silicon oxide, silicon nitride, and silicon oxynitride, and may include plural layers or a single layer including the materials described above.

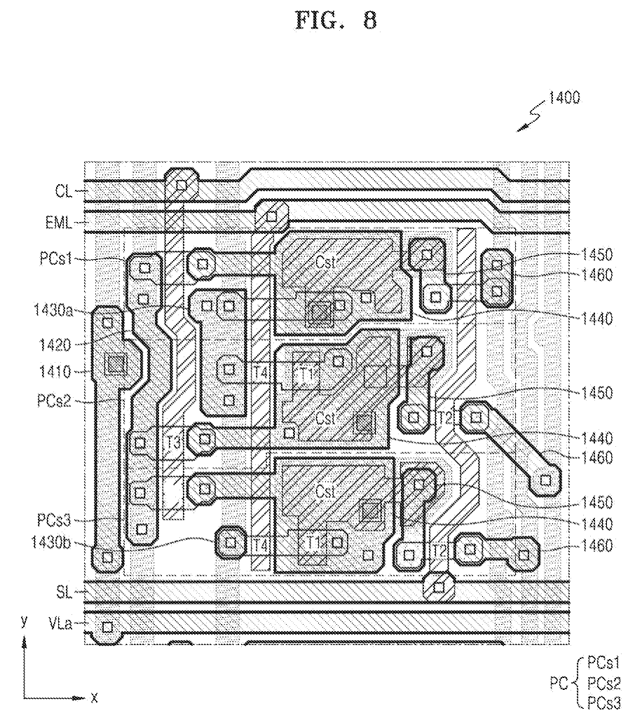

Referring to FIGS. 8 and 9 together, a third conductive layer 1400 may be arranged on the third insulating layer 105. The third conductive layer 1400 may include a conductive material, such as Mo, Al, Cu, Ti, etc., and may include plural layers or a single layer including the materials described above. The third conductive layer 1400 may include the control line CL, the emission control line EML, the scan line SL, the auxiliary voltage line VLa, a sixth conductive pattern 1410, a seventh conductive pattern 1420, an eighth-1 conductive pattern 1430a, an eighth-2 conductive pattern 1430b, ninth conductive patterns 1440, tenth conductive patterns 1450, and eleventh conductive patterns 1460.

The control line CL may extend in the second direction (for example, the x axis direction) and may be electrically connected to the fourth conductive pattern 1330 through a contact hole passing through the third insulating layer 105. The control line CL may be configured to supply the control signal CS (see FIG. 4) to the third gate electrodes G3.

The emission control line EML may extend in the second direction (for example, the x axis direction) and may be arranged to be adjacent to the control line CL in a plan view. According to one or more embodiments, the emission control line EML may be arranged between the control line CL and the pixel circuit PC in a plan view. The emission control line EML may be electrically connected to the fifth conductive pattern 1340 through a contact hole passing through the third insulating layer 105. The emission control line EML may be configured to supply the emission control signal EM (see FIG. 4) to the fourth gate electrodes G4.

The scan line SL may extend in the second direction (for example, the x axis direction) and may be electrically connected to the third conductive pattern 1320 through a contact hole passing through the third insulating layer 105. The scan line SL may be configured to supply the scan signal SS (see FIG. 4) to the second transistors T2.

The auxiliary voltage line VLa may extend in the second direction (for example, the x axis direction). The auxiliary voltage line VLa may be electrically connected to the common voltage line VSSL or the driving voltage line PL extending in the first direction (for example, the y axis direction) to form a mesh structure. Through the mesh structure, brightness deviation between sub-pixels due to a voltage drop of the common power voltage ELVSS (see FIG. 4) or the driving power voltage ELVDD (see FIG. 4) may be reduced. With respect to this aspect, FIGS. 5 to 7 illustrate that the auxiliary voltage line VLa is electrically connected to the common voltage line VSSL.

The sixth conductive pattern 1410 may overlap the common voltage line VSSL in a plan view. The sixth conductive pattern 1410 may be electrically connected to the common voltage line VSSL through a contact hole passing through the first to third insulating layers 101, 103, and 105. The sixth conductive pattern 1410 may be electrically connected to a common electrode 230 of the light-emitting diode LED through an auxiliary electrode and may be configured to transmit the common power voltage ELVSS (see FIG. 4) to the common electrode 230.

The seventh conductive pattern 1420 may overlap the initialization-sensing line ISL in a plan view. The seventh conductive pattern 1420 may be electrically connected to the initialization-sensing line ISL through contact holes passing through the first to third insulating layers 101, 103, and 105 and may be electrically connected to the third semiconductor patterns 1230 through contact holes passing through the second and third insulating layers 103 and 105. The seventh conductive pattern 1420 may electrically connect the initialization-sensing line ISL to the third source area S3 of the third transistor T3 of each of the first to third sub-pixel circuits PCs1 to PCs3. Through the seventh conductive pattern 1420, the initialization-sensing line ISL may be configured to transmit the initialization-sensing signal ISS (see FIG. 4) to the third transistor T3 of each of the first to third sub-pixel circuits PCs1 to PCs3.

The eighth-1 conductive pattern 1430a may overlap the driving voltage line PL in a plan view. The eighth-1 conductive pattern 1430a may be electrically connected to the driving voltage line PL through a contact hole passing through the first to third insulating layers 101, 103, and 105 and may be electrically connected to the first semiconductor pattern 1210 of each of the first and second sub-pixel circuits PCs1 and PCs2 through contact holes passing through the second and third insulating layers 103 and 105. The eighth-1 conductive pattern 1430a may electrically connect the driving voltage line PL to the fourth drain area D4 of the fourth transistor T4 of each of the first and second sub-pixel circuits PCs1 and PCs2. Through the eighth-1 conductive pattern 1430a, the driving voltage line PL may be configured to transmit the driving power voltage ELVDD (see FIG. 4) to the fourth transistor T4 of each of the first and second sub-pixel circuits PCs1 and PCs2.

The eighth-2 conductive pattern 1430b may overlap the driving voltage line PL in a plan view. The eighth-2 conductive pattern 1430b may be electrically connected to the driving voltage line PL and the first semiconductor pattern 1210 of the third sub-pixel circuit PCs3 through contact holes passing through the first to third insulating layers 101, 103, and 105. The eighth-2 conductive pattern 1430b may electrically connect the driving voltage line PL to the fourth drain area D4 of the fourth transistor T4 of the third sub-pixel circuit PCs3. Through the eighth-2 conductive pattern 1430b, the driving voltage line PL may be configured to transmit the driving power voltage ELVDD to the fourth transistor T4 of the third sub-pixel circuit PCs3.

The ninth conductive pattern 1440 may be provided in each of the first to third sub-pixel circuits PCs1 to PCs3. The ninth conductive pattern 1440 may overlap the first conductive pattern 1110, the second conductive patterns 1310, and the first semiconductor pattern 1210 in a plan view. The ninth conductive pattern 1440 may be electrically connected to the first conductive pattern 1110 through a contact hole passing through the first to third insulating layers 101, 103, and 105 and may be electrically connected to the first semiconductor pattern 1210 and the third semiconductor pattern 1230 through contact holes passing through the first to third insulating layers 101, 103, and 105. The ninth conductive pattern 1440 may electrically connect the first source area S1 of the first transistor T1, the third drain area D3 of the third transistor T3, and the lower electrode of the storage capacitor Cst to each other.

The tenth conductive pattern 1450 may be provided in each of the first to third sub-pixel circuits PCs1 to PCS3. The tenth conductive pattern 1450 may overlap the second conductive pattern 1310 and the second semiconductor pattern 1220 in a plan view. The tenth conductive pattern 1450 may be electrically connected to the second conductive pattern 1310 through a contact hole passing through the third insulating layer 105 and may be electrically connected to the second semiconductor pattern 1220 through a contact hole passing through the second and third insulating layers 103 and 105. The tenth conductive pattern 1450 may electrically connect the first gate electrode G1 of the first transistor T1, the upper electrode of the storage capacitor Cst, and the second source area S2 of the second transistor T2 to each other.

The eleventh conductive pattern 1460 may be provided in each of the first to third sub-pixel circuits PCs1 to PCs3. The eleventh conductive pattern 1460 may overlap the second semiconductor pattern 1220 and a corresponding data line in a plan view. The eleventh conductive pattern 1460 may be electrically connected to the corresponding data line through a contact hole passing through the first to third insulating layers 101, 103, and 105 and may be electrically connected to the second semiconductor pattern 1220 through a contact hole passing through the second and third insulating layers 103 and 105. The eleventh conductive pattern 1460 of the first sub-pixel circuit PCs1 may electrically connect the first data line DL1 to the second drain area D2 of the second transistor T2 of the first sub-pixel circuit PCs1. The eleventh conductive pattern 1460 of the second sub-pixel circuit PCs2 may electrically connect the second data line DL2 to the second drain area D2 of the second transistor T2 of the second sub-pixel circuit PCs2. The eleventh conductive pattern 1460 of the third sub-pixel circuit PCs3 may electrically connect the third data line DL3 to the second drain area D2 of the second transistor T2 of the third sub-pixel circuit PCs3.

In a plan view, the fifth conductive pattern 1340 may be arranged between the driving voltage line PL and the first conductive pattern 1110 included in the storage capacitor Cst. Thus, by optimizing the layout of the pixel circuit PC, the storage capacitor Cst may obtain a sufficient area.

A fourth insulating layer 107 may be arranged on the third conductive layer 1400. The fourth insulating layer 107 may include an organic insulating material and/or an inorganic insulating material and may include plural layers or a single layer including the materials described above.

Referring to FIG. 9, the light-emitting diode LED may be arranged on the fourth insulating layer 107. The light-emitting diode LED of FIG. 9 may indicate the first light-emitting diode LED 1 (see FIG. 2) electrically connected to the first sub-pixel circuit PCs1. The light-emitting diode LED may include a pixel electrode 210, the common electrode 230 arranged on the pixel electrode 210, and an intermediate layer 220 arranged between the pixel electrode 210 and the common electrode 230.

The pixel electrode 210 may be electrically connected to the ninth conductive pattern 1440 through a contact hole passing through the fourth insulating layer 107. The contact hole may provide a direct path for electrical connection between the pixel electrode 210 and the ninth conductive pattern 1440. The pixel electrode 210 may include a (semi-) transmissive electrode or a reflective electrode. The pixel electrode 210 may include a reflective layer including Ag, Mg, Al, Pt, Pd, Au, Ni, Nd, Ir, Cr, or any compound thereof, and a transparent or semi-transparent electrode layer on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), or aluminum zinc oxide (AZO). For example, the pixel electrode 210 may have a triple-layered structure of ITO/Ag/ITO.

A bank layer 109 may be arranged on the fourth insulating layer 107 and the pixel electrode 210. The bank layer 109 may be formed by spin coating, etc. by including at least one organic insulating material selected from the group consisting of polyimide, polyamide, acryl resins, BCB, and phenol resins.

The bank layer 109 may have (or define) a pixel opening exposing a central portion of the pixel electrode 210 and may cover an edge of the pixel electrode 210. The bank layer 109 may increase a distance between the edge of the pixel electrode 210 and the common electrode 230, thereby preventing the occurrence of electrical arcs or other issues at the edge of the pixel electrode 210.

The intermediate layer 220 may be arranged between the pixel electrode 210 and the common electrode 230, and at least a portion of the intermediate layer 220, for example, an emission layer 222, may be arranged to correspond to or align with the pixel opening. The emission layer 222 may include an organic material including a fluorescent or phosphorescent material for emitting red, green, blue, or white light. The emission layer 222 may include a low-molecular weight organic material or a high-molecular weight organic material. According to another embodiment, the emission layer 220 may be commonly formed across the plurality of pixel electrodes 210.

The intermediate layer 220 may include a first functional layer 221 and a second functional layer 223 commonly formed across the plurality of pixel electrodes 210. The first functional layer 221 may be arranged between the pixel electrode 210 and the emission layer 222, and the second functional layer 223 may be arranged between the emission layer 222 and the common electrode 230. Each of the first functional layer 221 and the second functional layer 223 may selectively include one or more of a hole transport layer (HTL), a hole injection layer (HIL), an electron transport layer (ETL), and an electron injection layer (EIL). One of the first functional layer 221 and the second functional layer 223 may be omitted.

The common electrode 230 may be arranged on the intermediate layer 220. The common electrode 230 may include a transmissive electrode or a reflective electrode. For example, the common electrode 230 may include a transparent or a transflective electrode and may include a metal thin layer having a small work function including Li, Ca, LiF, Al, Ag, Mg, and a compound thereof. Also, the common electrode CE may further include a transparent conductive oxide (TCO) layer, such as ITO, IZO, ZnO, or In₂O₃, arranged on the metal thin layer. The common electrode 230 may be integrally formed across the entire surface of the display area DA (see FIG. 1) and may be arranged above the plurality of pixel electrodes.

An encapsulation layer may be arranged on the light-emitting diode LED. The encapsulating layer may include at least one inorganic encapsulating layer and at least one organic encapsulating layer. For example, the encapsulation layer may have a structure in which a first inorganic encapsulation layer, an organic encapsulation layer, and a second inorganic encapsulation layer are sequentially stacked.

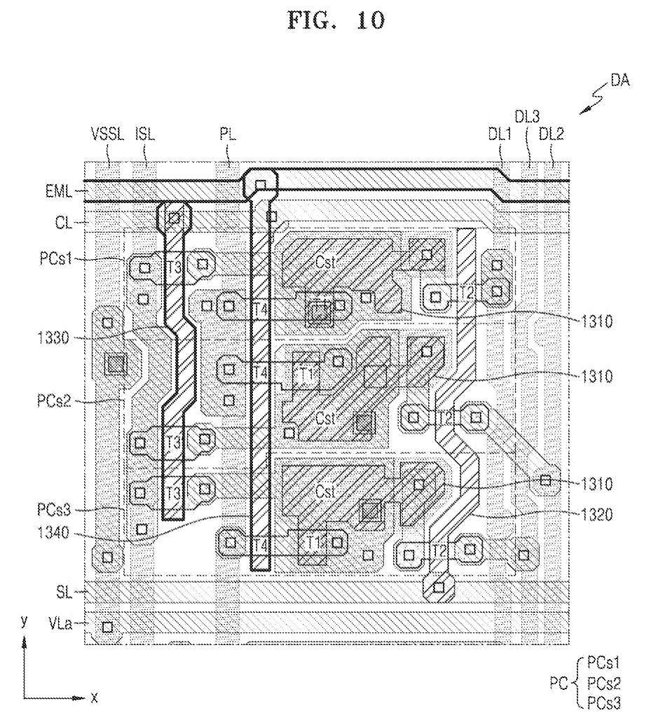

FIGS. 10 to 12 are each a schematic plan view of a portion of a display apparatus according to one or more embodiments.

FIGS. 10 to 12 are substantially the same as FIG. 5, but are different from FIG. 5 in an arrangement of the emission control line EML. Hereinafter, the same or repeated descriptions are omitted, and different aspects are mainly described.

Referring to FIG. 10, in a unit area repeated in a first direction (for example, a y axis direction) and a second direction (for example, an x axis direction), the emission control line EML, the control line CL, the scan line SL, and the auxiliary voltage line VLa may be sequentially arranged in the first direction (for example, the y axis direction). The pixel circuit PC may be arranged between the control line CL and the scan line SL.

The emission control line EML may extend in the second direction (for example, the x axis direction) and may be arranged to be adjacent to the control line CL. The emission control line EML may extend in the same direction as the control line CL. The emission control line EML may be arranged above (for example, a +y axis direction) the pixel circuit PC, and the control line CL may be arranged between the emission control line EML and the pixel circuit PC in a plan view.

In the unit area, the common voltage line VSSL, the initialization-sensing line ISL, the driving voltage line PL, the first data line DL1, the third data line DL3, and the second data line DL2 may be sequentially arranged in the second direction (for example, the x axis direction). The fourth conductive pattern 1330 may be arranged between the initialization-sensing line ISL and the driving voltage line PL. The fourth conductive pattern 1330 may be electrically connected to the control line CL and may include the third gate electrode G3 of the third transistor T3 of each of the first to third sub-pixel circuits PCs1 to PCs3.

The fifth conductive pattern 1340 may be arranged between the driving voltage line PL and the storage capacitor Cst in a plan view. In other words, the fifth conductive pattern 1340 may be arranged between the driving voltage line PL and the lower electrode of the storage capacitor Cst, for example, the first conductive pattern 1110 (see FIG. 6), in a plan view. The fifth conductive pattern 1340 may be electrically connected to the emission control line EML and may include the fourth gate electrode G4 of the fourth transistor T4 of each of the first to third sub-pixel circuits PCs1 to PCs3.

The third conductive pattern 1320 may be arranged between the storage capacitor Cst and the first to third data lines DL1 to DL3 in a plan view. In other words, the third conductive pattern 1320 may be arranged between the lower electrode of the storage capacitor Cst, for example, the first conductive pattern 1110, and the first data line DL1, in a plan view. The third conductive pattern 1320 may be electrically connected to the scan line SL and may include the second gate electrode G2 of the second transistor T2 of each of the first to third sub-pixel circuits PCs1 to PCs3.

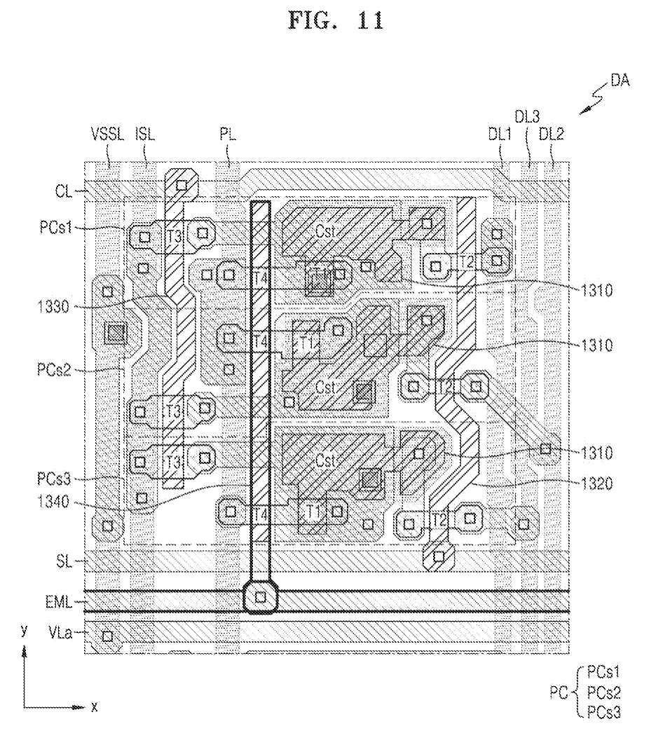

Referring to FIG. 11, in a unit area, the control line CL, the scan line SL, the emission control line EML, and the auxiliary voltage line VLa may be sequentially arranged in a first direction (for example, a y axis direction). The pixel circuit PC may be arranged between the control line CL and the scan line SL in a plan view. The emission control line EML may extend in a second direction (for example, an x axis direction) and may be arranged below (for example, a -y axis direction) the pixel circuit PC. The emission control line EML may extend in the same direction as the scan line SL. The emission control line EML may be arranged to be adjacent to the scan line SL in a plan view, and the scan line SL may be arranged between the emission control line EML and the pixel circuit PC in the plan view.

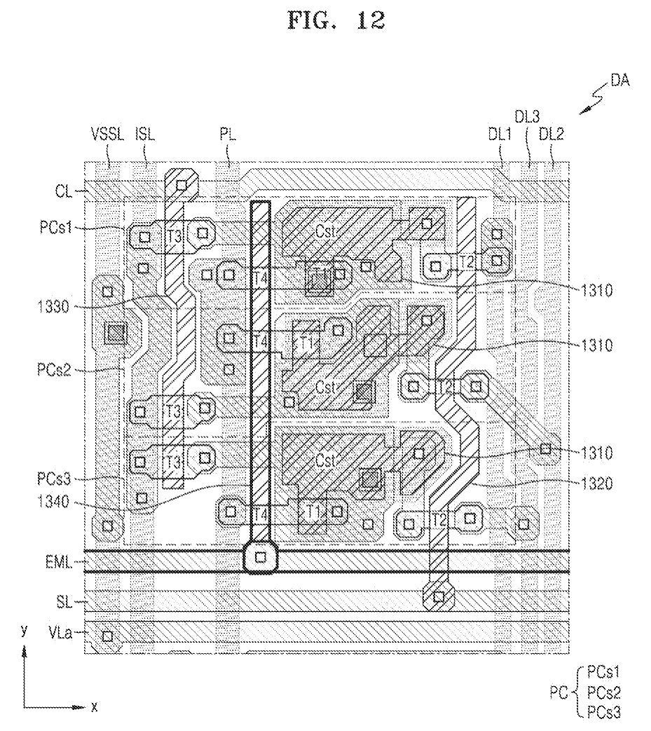

Referring to FIG. 12, in a unit area, the control line CL, the emission control line EML, the scan line SL, and the auxiliary voltage line VLa may be sequentially arranged in a first direction (for example, a y axis direction). The pixel circuit PC may be arranged between the control line CL and the emission control line EML in a plan view. The emission control line EML may extend in a second direction (for example, an x axis direction) and may be arranged below (for example, a -y axis direction) the pixel circuit PC. The emission control line EML may extend in the same direction as the scan line SL. The emission control line EML may be arranged to be adjacent to the scan line SL in a plan view. For example, the emission control line EML may be arranged between the scan line SL and the pixel circuit PC in a plan view.

According to embodiments, the layout of the pixel circuit PC may be optimized to efficiently allocate space for the storage capacitor Cst. Also, the incorporation of the fourth transistor T4 effectively controls the path of the driving current flowing from the driving voltage line PL to the light-emitting diode LED, and thus, an image having improved quality may be displayed.

The display apparatus according to one or more embodiments may be employed by various electrode devices. An electronic device according to one or more embodiments may include the display apparatus described above and may further include a module or a device having other additional functions in addition to the display apparatus.

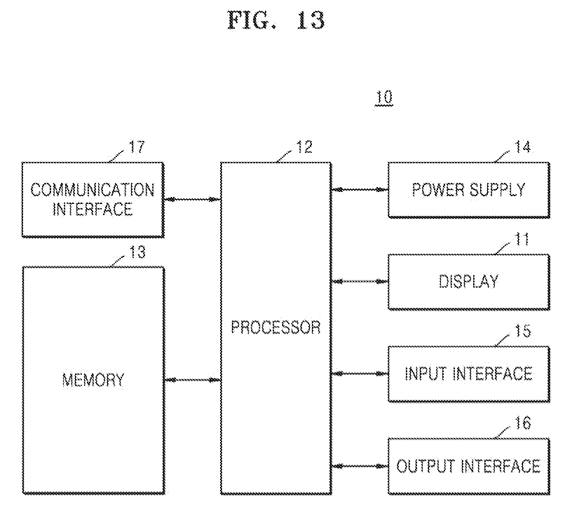

FIG. 13 is a block diagram of an electronic device 10 according to one or more embodiments.

Referring to FIG. 13, the electronic device 10 according to one or more embodiments may include a display 11, a processor 12, a memory 13, and a power supply 14. The electronic device 10 may further include an input interface 15, an output interface 16, and/or a communication interface 17.

The electronic device 10 may output, through the display 11, various information in the form of an image. When the processor 12 executes an application stored in the memory 13, image information provided by the application may be provided to a user through the display 11.

According to one or more embodiments, the processor 12 may be provided by being divided into two or more processors in a functional or structural perspective. For example, the processor 12 may include a main processor as a first driving chip including a CPU and an auxiliary processor as a second driving chip including a controller configured to receive an image signal from the main processor and process the image signal according to the interface specifications of the display 11.

The memory 15 may include at least one of a non-volatile memory and a volatile memory. The memory 15 may store data information necessary for operations of the processor 12 or the display 11. When the processor 12 executes an application stored in the memory 15, an image data signal and/or an input control signal may be transmitted to the display 11, and the display 11 may be configured to process the received signal and output image information through a display screen.

The power supply 14 may include a power adaptor or a battery to supply power, and a power converter configured to convert the power necessary for operations of the electronic device 10. The power converter may perform direct current (DC)-DC conversion, alternating current (AC)-DC conversion, and DC-AC conversion and is not limited thereto.

The input interface 15 may provide input information to the processor 12 and/or the display 11. The input interface 15 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc.

The output interface 16 may receive information except for an image from the processor 12 and provide the information to the user. Examples of the output interface 16 may include a speaker, a haptic module (e.g., a motor or a vibrator), a light-emission module (e.g., a light emitting diode (LED) or a laser), etc. and may also include other functionally intrinsic modules (for example, a cooling module of a refrigerator, etc.) of the electronic device 10.

The communication interface 17 may be configured to perform transmission and reception of information between the electronic device 10 and an external device and may include a receiver and a transmitter. The communication interface 17 may include various wireless communication interfaces, such as a mobile communication interface, a WiFi module, a Bluetooth module, etc., or various wired communication interfaces.

At least of the components of the electronic device 10 described above may be included in the display apparatus DV (see FIG. 1) according to the embodiments described above. Also, some of separate modules functionally included in one module may be included in the display apparatus DV and the others may be provided separately from the display apparatus DV. For example, the display apparatus DV may include the display 11, and the processor 12, the memory 13, and the power module 14 may be provided in the electronic device 11 as other devices, rather than the display apparatus DV. As another example, the power module 14 may be provided in the display apparatus DV and may provide a power supply to the processor 12 and the memory 13 in the electronic device 11, rather than the display apparatus DV. However, the disclosure is not limited thereto.

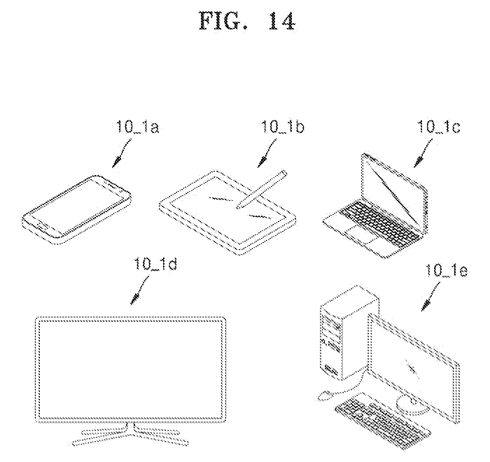

FIGS. 14 to 16 are schematic views of electronic devices according to various embodiments.

FIGS. 14 to 16 illustrate examples of various electronic devices employing the display apparatus DV (see FIG. 1) according to embodiments.

FIG. 14 illustrates a smartphone 10_1a, a tablet PC 10_1b, a laptop computer 10_1c, a TV 10_1d, and a monitor 10_1e for a desk, as examples of the electronic devices.

The smartphone 10_1a may include an input interface, such as a touch sensor, etc., and a communication interface, in addition to the display 11. The smartphone 10_1a may process information received through the communication interface or other input interfaces and display the processed information through a display of the display apparatus DV.

The tablet PC 10_1b, the laptop computer 10_1c, the TV 10_1d, and the monitor 10_1e for a desk may also include a display and an input interface, similarly as the smartphone 10_1a, and may further include a communication interface according to cases.

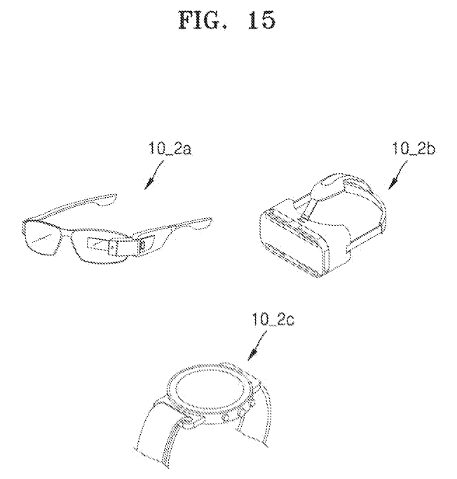

FIG. 15 illustrates a case where an electronic device including a display is employed by a wearable electronic device. The wearable electronic device may include smart glasses 10_2a, an HMD 10_2b, a smart watch 10_2c, etc.

The smart glasses 10_2a and the HMD 10_2b may include a display configured to project a display image and a reflector configured to reflect the projected display screen and provide the display screen to a user’s eye, so as to provide a screen of virtual reality (VR) or augmented reality (AR) to the user.

The smart watch 10_2c may include a biometric sensor as an input device and may provide biometric information recognized through the biometric sensor to the user through a display.

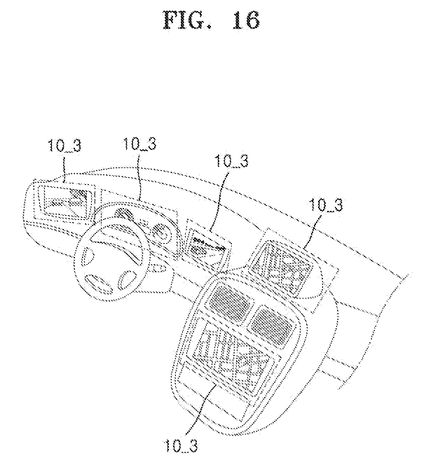

FIG. 16 illustrates a case where an electronic device including a display is employed by a vehicle. For example, an electronic device 10_3 may be used as a gauge or a center fascia of the vehicle or may be used as a center information display (CID) arranged on a dashboard of the vehicle or as a room mirror display substituting a side-view mirror.

Although not shown, the electronic device employing the display apparatus DV according to embodiments may include not only devices mainly used for a screen display, such as an advertisement board, an electronic display board, a game machine, etc., but also various home appliances for displaying information through a display, such as a refrigerator, a laundry machine, a dryer, an air conditioner, a robot cleaner, etc. Also, when a display has a light-transmission function, the display may be employed by the electronic device, such as a smart window or a transparent display apparatus for displaying a background and a display image together. Types of the electronic device according to one or more embodiments are not limited to the examples described above, and various other electronic devices may also be provided.

According to one or more embodiments as described above, a display apparatus for providing a high-quality image and an electronic device including the display apparatus may be realized. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising a sub-pixel, the sub-pixel comprising:
a sub-pixel circuit;
a driving voltage line and a data line that extend in a first direction;
an emission control line that extend in a second direction crossing the first direction; and
a light-emitting diode,
wherein the sub-pixel circuit comprises:
a driving transistor connected between the driving voltage line and the light-emitting diode;
a data write transistor connected between the driving transistor and the data line;
an emission control transistor connected between the driving voltage line and the driving transistor; and
a first conductive pattern connected to the emission control line and comprising a gate electrode of the emission control transistor,
wherein the first conductive pattern is between the driving voltage line and the driving transistor in a plan view.

2. The display apparatus of claim 1, wherein the first conductive pattern extends in the first direction.

3. The display apparatus of claim 1, further comprising:
an initialization-sensing line extending in the first direction; and
a control line extending in the second direction,
wherein the sub-pixel circuit further comprises:
an initialization-sensing transistor connected between the initialization-sensing line and the light-emitting diode; and
a second conductive pattern connected to the control line and comprising a gate electrode of the initialization-sensing transistor.

4. The display apparatus of claim 3, wherein the emission control line is closer to the control line than to a scan line of the sub-pixel in the plan view.

5. The display apparatus of claim 4, wherein the emission control line is between the control line and the sub-pixel circuit in the plan view.

6. The display apparatus of claim 4, wherein the control line is between the emission control line and the sub-pixel circuit in the plan view.

7. The display apparatus of claim 1, further comprising a scan line extending in the second direction,
wherein the sub-pixel circuit further comprises a third conductive pattern connected to the scan line and comprising a gate electrode of the data write transistor.

8. The display apparatus of claim 7, wherein the emission control line is closer to the scan line than to the control line.

9. The display apparatus of claim 8, wherein the emission control line is between the scan line and the sub-pixel circuit.

10. The display apparatus of claim 8, wherein the scan line is between the emission control line and the sub-pixel circuit.

11. A display apparatus comprising:
a first conductive layer comprising a driving voltage line extending in a first direction;
a semiconductor layer on the first conductive layer and comprising a first semiconductor pattern;
a second conductive layer on the semiconductor layer and comprising a first gate electrode overlapping a portion of the first semiconductor pattern and a first conductive pattern overlapping another portion of the first semiconductor pattern; and
a third conductive layer on the second conductive layer and comprising an emission control line extending in a second direction crossing the first direction,
wherein the first conductive pattern extends in the first direction between the driving voltage line and the first gate electrode in a plan view.

12. The display apparatus of claim 11, wherein the first conductive layer further comprises an initialization-sensing line extending in the first direction,
the semiconductor layer further comprises a second semiconductor pattern connected to the initialization-sensing line,
the second conductive layer further comprises a second conductive pattern extending in the first direction and overlapping the second semiconductor pattern, and
the third conductive layer further comprises a control line extending in the second direction and connected to the second conductive pattern.

13. The display apparatus of claim 12, wherein the emission control line is closer to the control line than to the scan line in the plan view.

14. The display apparatus of claim 13, wherein the emission control line is between the control line and the first gate electrode in the plan view.

15. The display apparatus of claim 13, wherein the control line is between the emission control line and the first gate electrode in the plan view.

16. The display apparatus of claim 11, wherein the first conductive layer further comprises a data line extending in the first direction,
the semiconductor layer further comprises a third semiconductor pattern connected to the data line,
the second conductive layer further comprises a third conductive pattern extending in the first direction and overlapping the third semiconductor pattern, and
the third conductive layer further comprises a scan line extending in the second direction and connected to the third conductive pattern.

17. The display apparatus of claim 16, wherein the emission control line is closer to the scan line than to the control line in the plan view.

18. An electronic device comprising:
the display apparatus according to claim 1;
a memory storing an application; and
a processor configured to execute the application and transmit an image data signal and an input control signal to the display apparatus.

19. An electronic device comprising:
the display apparatus according to claim 11;
a memory storing an application; and
a processor configured to execute the application and transmit an image data signal and an input control signal to the display apparatus.

20. An electronic device comprising a pixel,
wherein the pixel comprises:
a sensing line, a driving voltage line, and a data line that are sequentially arranged in a horizontal direction in a plan view of the pixel;
a light emitting diode (LED); and
a pixel circuit comprising:
a first transistor between the driving voltage line and the LED;
a storage capacitor connected between a gate electrode of the first transistor and the LED;
a second transistor connected between the data line and the gate electrode of the first transistor;
a third transistor connected between the sensing line and the LED; and
a fourth transistor connected between the driving voltage line and the first transistor,
wherein a gate electrode of the fourth transistor is connected to an emission control line that extends in the horizontal direction in the plan view, and
wherein a gate wiring of the fourth transistor extends in a vertical direction and is between the driving voltage line and the storage capacitor in the plan view.
